(19) United States
(12) Patent Application Publication
(10) Pub. No.: US 2012/0112342 A1
(43) Pub. Date: May 10, 2012

(54) SEMICONDUCTOR DEVICE AND STACKED SEMICONDUCTOR PACKAGE

(75) Inventors: Sung Ho HYUN, Seoul (KR); Qwan Ho CHUNG, Seoul (KR); Myung Gun PARK, Seoul (KR)

(73) Assignee: HYNIX SEMICONDUCTOR INC., Icheon-si (KR)

(21) Appl. No.: 13/242,885

(22) Filed: Sep. 23, 2011

(30) Foreign Application Priority Data
Nov. 8, 2010 (KR) 10-2010-0110237

(51) Int. Cl. H01L 23/485

(52) U.S. Cl. 257/737; 257/E23.021

(57) ABSTRACT

A semiconductor device includes a first structural body having a first surface and a second surface which faces away from the first surface, and formed with first electrode pads on the first surface, a stress buffer layer formed on the first electrode pads and the first surface of the first structural body, and having a plurality of holes which expose the first electrode pads, and a plurality of bumps formed to be electrically connected with the first electrode pads through the plurality of holes, wherein the plurality of bumps include first bumps which are filled in corresponding holes of the plurality of holes and second bumps which are formed on the first bumps and the stress buffer layer and are disposed over the first electrode pads and portions of the first surface outside the first electrode pads.

### CROSS-REFERENCE TO RELATED APPLICATIONS

The present application claims priority to Korean patent application number 10-2010-110237 filed on Nov. 8, 2010, which is incorporated herein by reference in its entirety.

### BACKGROUND OF THE INVENTION

The present invention relates to a semiconductor device and a stacked semiconductor package.

Recently, a semiconductor package is being made light, slim and compact in order to accommodate trends toward miniaturization, light weight and high performance of electronic appliances. Accordingly, a semiconductor package having a short length of wiring for transferring electrical signals, small resistance, small inductance, good signal transfer characteristics and good noise characteristics is demanded. In order to improve the signal transfer characteristics, and noise characteristics, a flip chip bonding method using bumps is being developed to replace existing wiring bonding method.

In the flip chip boning method, the bumps to be used as connection electrodes are formed on electrode pads of semiconductor chips such that electrical and mechanical connections between the semiconductor chip and a substrate or between the semiconductor chips are formed by the bumps. In the flip chip bonding method, since electrical signals is transferred through the bumps, a path of signal becomes shortened, therefore an operation speed of a semiconductor package may increase, and the size of the semiconductor package may decrease.

However, the flip chip bonding method may be disadvantageous in terms of reliability of joints. Describing in detail, warpage may occur owing to the stresses induced in a molding process or a thermal process. Here, in the thermal process, the warpage may occur by different heat expansion coefficients of component parts constituting the semiconductor package, and due to this fact, poor junctions, e.g., detachment of the bumps may be caused as the bumps are detached. The problems caused due to the poor junctions can be solved by forming the bumps in a plural number. Nevertheless, because positions at which the bumps are formed are limited to the electrode pads of the semiconductor chip, firm coupling among component parts cannot be ensured. Also, if a poor junction is caused in even any one of the bumps, a corresponding product cannot be used, and thus the manufacturing yield may decrease.

### BRIEF SUMMARY OF THE INVENTION

Embodiments of the present invention are directed to a semiconductor device and a stacked semiconductor package having the same, which can reduce the occurrence of poor junctions of bumps and improve the manufacturing yield.

In an exemplary embodiment of the present invention, a semiconductor device includes a first structural body having a first surface and a second surface which faces away from the first surface, and formed with first electrode pads on the first surface, a stress buffer layer formed on the first electrode pads and the first surface of the first structural body, and having a plurality of holes which expose each of the first electrode pads, and a plurality of bumps formed to be electrically connected with the first electrode pads through the plurality of holes, wherein the plurality of bumps include first bumps which are filled in corresponding holes of the plurality of holes and second bumps which are formed on the first bumps and the stress buffer layer and are disposed over the first electrode pads and portions of the first surface outside the first electrode pads.

The semiconductor device may further include UBMs formed between the plurality of bumps and the stress buffer layer and the first electrode pads.

The plurality of holes may be defined in such a way as to expose peripheral portions of the first electrode pads.

The second bumps may have pillar shapes.

The semiconductor device may further include a second structural body having a third surface which faces the first surface of the first structural body and a fourth surface which faces away from the third surface, and formed, on the third surface, with second electrode pads each of which is simultaneously connected with at least two of the plurality of bumps.

Each of the first structural body and the second structural body may include any one of a semiconductor device and a printed circuit board.

The semiconductor device may be any one selected from the group consisting of an image sensor, a memory semiconductor, a system semiconductor, a passive device, an active device and a sensor semiconductor.

The printed circuit board may be any one selected from the group consisting of a module substrate, a package substrate, a flexible substrate and a main board.

The semiconductor device may further include a second structural body having a third surface which faces the first surface of the first structural body and a fourth surface which faces away from the third surface, and formed, on the third surface, with a plurality of second electrode pads which are respectively connected with the plurality of bumps.

Each of the first structural body and the second structural body may include any one of a semiconductor device and a printed circuit board.

The semiconductor device may be any one selected from the group consisting of an image sensor, a memory semiconductor, a system semiconductor, a passive device, an active device and a sensor semiconductor.

The printed circuit board may be any one selected from the group consisting of a module substrate, a package substrate, a flexible substrate and a main board.

In another exemplary embodiment of the present invention, a stacked semiconductor package includes a stacked semiconductor chip module including a first semiconductor chip which has a first surface and a second surface facing away from the first surface and is formed, on the first surface, with first electrode pads and redistribution lines connected with the first electrode pads, a second semiconductor chip which is stacked over the first semiconductor chip and is formed, on a third surface thereof facing the first semiconductor chip, with second electrode pads, a stress buffer layer which is formed on the third surface of the second semiconductor chip and the second electrode pads and has a plurality of holes exposing each of the second electrode pads, and a plurality of bumps which are formed to be electrically connected with the second electrode pads through the plurality of holes, a substrate supporting the stacked semiconductor chip module, and connection members electrically connecting the redistribution lines of the second semiconductor chip and the substrate, wherein the plurality of bumps include first bumps which are filled in corresponding holes of the plurality of holes and second bumps which are formed on the first bumps and the stress buffer layer and are disposed over the second electrode pads and portions of the third surface outside the second electrode pads.

The stacked semiconductor package may further include UBMs formed between the plurality of bumps and the stress buffer layer and the second electrode pads.

The plurality of holes may be defined in such a way as to expose peripheral portions of the second electrode pads of the second semiconductor chip.

The second bumps have pillar shapes.

The stacked semiconductor package may further include: a mold member sealing an upper surface of the substrate including the stacked semiconductor chip module; and external connection terminals mounted to a lower surface of the substrate which faces away from the upper surface.

Each of the first semiconductor chip and the second semiconductor chip may include any one selected from the group consisting of an image sensor, a memory semiconductor, a system semiconductor, a passive device, an active device and a sensor semiconductor.

The substrate may be any one selected from the group consisting of a module substrate, a package substrate, a flexible substrate and a main board.

### BRIEF DESCRIPTION OF THE DRAWINGS

FIG. 1 is a plan view illustrating a semiconductor device in accordance with an exemplary embodiment of the present invention.

FIG. 2 is a cross-sectional view taken along the line I-I′ of FIG. 1.

FIG. 3 is a cross-sectional view illustrating a semiconductor device in accordance with another exemplary embodiment of the present invention.

FIG. 4 is a cross-sectional view illustrating a semiconductor device in accordance with another exemplary embodiment of the present invention.

FIG. 5 is a cross-sectional view illustrating a stacked semiconductor package in accordance with another exemplary embodiment of the present invention.

### DESCRIPTION OF SPECIFIC EMBODIMENTS

Hereafter, specific embodiments of the present invention will be described in detail with reference to the accompanying drawings.

It is to be understood herein that the drawings are not necessarily to scale and in some instances proportions may have been exaggerated in order to more clearly depict certain features of the invention.

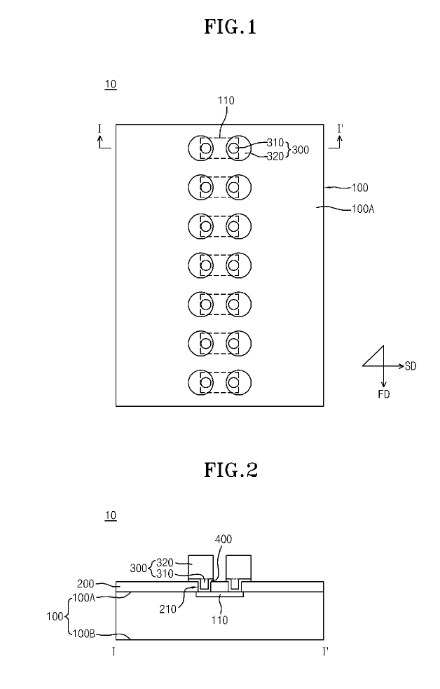

FIG. 1 is a plan view illustrating a semiconductor device in accordance with an exemplary embodiment of the present invention, and FIG. 2 is a cross-sectional view taken along the line I-I′ of FIG. 1.

Referring to FIGS. 1 and 2, a semiconductor device 10 in accordance with this exemplary embodiment of the present invention includes a first structural body 100, a stress buffer layer 200, and a plurality of bumps 300.

The first structural body 100 may be, for example, a semiconductor device such as an image sensor, a memory semiconductor, a system semiconductor, a passive device, an active device and a sensor semiconductor. Furthermore, the first structural body 100 may be a printed circuit board such as a module substrate, a package substrate, a flexible substrate and a main board.

The first structural body 100 has a first surface 100A and a second surface 100B which faces away from the first surface 100A. First electrode pads 110 are formed on the first surface 100A of the first structural body 100. The first structural body 100 may include a circuit unit (not shown) which has a data storage section (not shown) for storing data and a data processing section (not shown) for processing data. The first electrode pads 110 serve as electrical contacts of the circuit unit, for electrical connection to an outside. In the present exemplary embodiment, the first electrode pads 110 are formed in a plural number along a first direction FD as shown in FIG. 1.

According to an example, the stress buffer layer 200 is formed over the first electrode pads 110 and the first surface 100A of the first structural body 100, and has a plurality of holes 210 which expose each of the first electrode pads 110. The plurality of holes 210 are formed in such a way as to expose some portions, e.g., peripheral portions of the first electrode pads 110. In the present exemplary embodiment, the stress buffer layer 200 is formed with the holes 210 in such a manner that two holes 210 expose each of first electrode pad 110. In the present exemplary embodiment, the two holes 210 are arranged along a second direction SD which is, for example, perpendicular to the first direction FD. Between the two holes 210, one hole 210 is formed to expose one end of the first electrode pad 110, and the other hole 210 is formed to expose the other end of the first electrode pad 110 which faces away from the one end. As a material of the stress buffer layer 200, polymer may be used.

The plurality of bumps 300 are formed in such a way as to be electrically connected with the first electrode pads 110 through the plurality of holes 210.

The plurality of bumps 300 include first bumps 310 and second bumps 320. That is to say, each bump 300 has a double bump structure.

The first bumps 310 are respectively filled in corresponding holes 210. The second bumps 320 are formed on the first bumps 310 and portions of the stress buffer layer 200. In the present exemplary embodiment, the second bumps 320 have pillar shapes. The second bumps 320 are formed over the first electrode pads 110 and over the first surface 100A of the first structural body 100 outside the first electrode pads 110. In other words, the second bumps 320 are formed to be redistributed to the outsides of the first electrode pads 110. As a material of the bumps 300, solder or gold may be used.

According to an example, UBMs (under bump metals) 400 are formed between the plurality of bumps 300 and the stress buffer layer 200 and the first electrode pads 110.

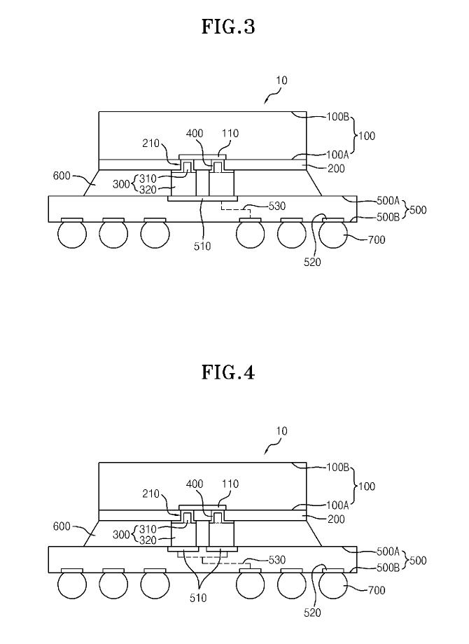

FIG. 3 is a cross-sectional view illustrating a semiconductor device in accordance with another exemplary embodiment of the present invention.

Referring to FIG. 3, a semiconductor device in accordance with this exemplary embodiment of the present invention has a structure in which the semiconductor device 10 described above with reference to FIGS. 1 and 2 is mounted to a second structural body 500 which has second electrodes pads 510, by the medium of the plurality of bumps 300. Therefore, repeated descriptions of the same component parts will be omitted herein, and the same terms and the same reference numerals will be used to refer to the same component parts.

The second structural body 500 may be, for example, a semiconductor device such as an image sensor, a memory semiconductor, a system semiconductor, a passive device, an active device and a sensor semiconductor. Furthermore, the second structural body 500 may be a printed circuit board such as a module substrate, a package substrate, a flexible substrate and a main board.

The second structural body 500 has a third surface 500A which faces the first surface 100A of the first structural body 100 and a fourth surface 500B which faces away from the third surface 500A. The second structural body 500 has the second electrode pads 510 which are connected to the plurality of bumps 300 connected to the first electrode pads 110, on the third surface 500A. In the present exemplary embodiment, two bumps 300 are simultaneously connected to one second electrode pad 510. The second structural body 500 has third electrode pads 520 on the fourth surface 500B. The second structural body 500 has therein circuit patterns 530 which include multiple layers of circuit wiring lines (not shown) and conductive vias (not shown) connecting the circuit wiring lines formed on different layers. The second electrode pads 510 and the third electrode pads 520 are electrically connected with each other by the circuit patterns 530.

In order to improve the reliability of joints, an underfill member 600 may be filled between the first structural body 100 and the second structural body 500. External connection terminals 700 such as solder balls are mounted to the third electrode pads 520, for connection to external devices.

FIG. 4 is a cross-sectional view illustrating a semiconductor device in accordance with another exemplary embodiment of the present invention.

Referring to FIG. 4, a semiconductor device in accordance with this exemplary embodiment of the present invention has a structure in which the semiconductor device 10 described above with reference to FIGS. 1 and 2 is mounted to a second structural body 500 which has a plurality of second electrodes pads 510, by the medium of the plurality of bumps 300. Therefore, repeated descriptions of the same component parts will be omitted herein, and the same terms and the same reference numerals will be used to refer to the same component parts.

The second structural body 500 may be, for example, a semiconductor device such as an image sensor, a memory semiconductor, a system semiconductor, a passive device, an active device and a sensor semiconductor. Furthermore, the second structural body 500 may be a printed circuit board such as a module substrate, a package substrate, a flexible substrate and a main board.

The second structural body 500 has a third surface 500A which faces the first surface 100A of the first structural body 100 and a fourth surface 500B which faces away from the third surface 500A. The second structural body 500 has the second electrode pads 510 which are respectively connected to the plurality of bumps 300 connected to the first electrode pads 110, on the third surface 500A. That is to say, one bump 300 is connected to one second electrode pad 510. The second structural body 500 has third electrode pads 520 on the fourth surface 500B. The second structural body 500 has therein circuit patterns 530 which include multiple layers of circuit wiring lines (not shown) and conductive vias (not shown) connecting the circuit wiring lines formed on different layers. The second electrode pads 510 and the third electrode pads 520 are electrically connected with each other by the circuit patterns 530.

In order to improve the reliability of joints, an underfill member 600 may be filled between the first structural body 100 and the second structural body 500. External connection terminals 700 such as solder balls are mounted to the third electrode pads 520, for connection to external devices.

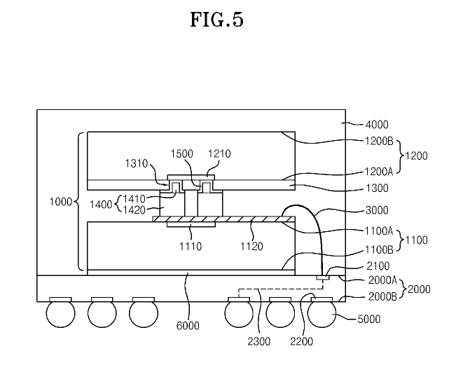

FIG. 5 is a cross-sectional view illustrating a stacked semiconductor package in accordance with another exemplary embodiment of the present invention.

Referring to FIG. 5, a stacked semiconductor package in accordance with this exemplary embodiment of the present invention includes a stacked semiconductor chip module 1000, a substrate 2000, and connection members 3000. In addition, the stacked semiconductor package may further include a mold member 4000 and external connection terminals 5000.

The stacked semiconductor chip module 1000 includes a first semiconductor chip 1100, a second semiconductor chip 1200, a stress buffer layer 1300, and a plurality of bumps 1400.

Each of the first and second semiconductor chips 1100 and 1200 may be any one of an image sensor, a memory semiconductor, a system semiconductor, a passive device, an active device and a sense semiconductor.

The first semiconductor chip 1100 has a first surface 1100A and a second surface 1100B which faces away from the first surface 1100A. First electrode pads 1110 are formed on the first surface 1100A of the first semiconductor chip 1100. In the present exemplary embodiment, the first electrode pads 1110 are formed in a plural number along the center portion of the first surface 1100A of the first semiconductor chip 1100. Namely, the first semiconductor chip 1100 has a center pad type structure.

According to an example, redistribution lines 1120 are formed on the first electrode pads 1110 and the first surface 1100A of the first semiconductor chip 1100 in such a way as to redistribute the first electrode pads 1110 to the edge of the first semiconductor chip 1100. One ends of the redistribution lines 1120 are connected with the first electrode pads 1110, and the other ends of the redistribution lines 1120, which face away from the one ends, are formed on the edge of the first semiconductor chip 1100.

The second semiconductor chip 1200 has a third surface 1200A which faces the first surface 1100A of the first semiconductor chip 1100 and a fourth surface 1200B which faces away from the third surface 1200A. Second electrode pads 1210 are formed on the third surface 1200A of the second semiconductor chip 1200.

The stress buffer layer 1300 has a plurality of holes 1310 which are formed on the second electrode pads 1210 and the third surface 1200A of the second semiconductor chip 1200 and expose the second electrode pads 1210. The plurality of holes 1310 are formed in such a way as to expose peripheral portions of the second electrode pads 1210. In the present exemplary embodiment, the stress buffer layer 1300 is formed with the holes 1310 in such a manner that two holes 1310 expose each second electrode pad 1210. One of the two holes 1310 exposes one end of the second electrode pad 1210 and the other of the two holes 1310 exposes the other end of the second electrode pad 1210, which faces away from the one end of the second electrode pad 1210. As a material of the stress buffer layer 1300, polymer may be used.

The plurality of bumps 1400 are formed in such a way as to be electrically connected with the second electrode pads 1210 through the plurality of holes 1310.

The plurality of bumps 1400 include first bumps 1410 and second bumps 1420. That is to say, each bump 1400 has a double structure. The first bumps 1410 are respectively filled in corresponding holes 1310. The second bumps 1420 are formed on the first bumps 1410 and portions of the stress buffer layer 1300. In the present exemplary embodiment, the second bumps 1420 have pillar shapes. The second bumps 1420 are formed over the second electrode pads 1210 and over the third surface 1200A of the second semiconductor chip 1200 outside the second electrode pads 1210. In other words, the second bumps 1420 are formed to be redistributed to the outsides of the second electrode pads 1210.

As a material of the bumps 1400, solder or gold may be used. UBMs 1500 are formed between the plurality of bumps 1400 and the stress buffer layer 1300 and the second electrode pads 1210.

The second semiconductor chip 1200 is stacked over the first semiconductor chip 1100 in such a manner that the plurality of bumps 1400 are connected with the redistribution lines 1120 of the first semiconductor chip 1100.

The substrate 2000 supports the stacked semiconductor chip module 1000. The substrate 2000 may be any one of a module substrate, a package substrate, a flexible substrate, and a main board.

The substrate 2000 has an upper surface 2000A which faces the stacked semiconductor chip module 1000 and a lower surface 2000B which faces away from the upper surface 2000A. The stacked semiconductor chip module 1000 is attached to upper surface 2000A of the substrate 2000 with an adhesive member 6000.

The substrate 2000 include bond fingers 2100, ball lands 2200 and circuit patterns 2300. The bond fingers 2100 are formed on the upper surface 2000A of the substrate 2000 outside the stacked semiconductor chip module 1000, and the ball lands 2200 are formed on the lower surface 2000B of the substrate 2000. The circuit patterns 2300 include multiple layers of circuit wiring lines (not shown) and conductive vias (not shown) connecting the circuit wiring lines formed on different layers. The circuit patterns 2300 electrically connect the bond fingers 2100 and the ball lands 2200.

The connection members 3000 electrically connect the redistribution lines 1120 of the first semiconductor chip 1100 and the bond fingers 2100 of the substrate 2000. The connection members 3000 include bonding wires.

The mold member 4000 seals the upper surface 2000A of the substrate 2000 including the stacked semiconductor chip module 1000, and the external connection terminals 5000 are mounted to the ball lands 2200 of the substrate 2000.

As is apparent from the above description, in the exemplary embodiments of the present invention, since at least two bumps are connected to one electrode pad, even when a poor junction is caused in a bump, an electrical connection may be maintained through another bump, by which the manufacturing yield may increase. Also, component parts constituting a semiconductor device can be firmly coupled with one another. Moreover, warpage of the semiconductor device is suppressed and a probability of a formation of a poor junction at the bumps may decrease.

Although specific embodiments of the present invention have been described for illustrative purposes, those skilled in the art will appreciate that various modifications, additions and substitutions are possible, without departing from the scope and the spirit of the invention as disclosed in the accompanying claims.

What is claimed is:

1. A semiconductor device comprising:
a first structural body having a first surface and a second surface which faces away from the first surface, and formed with first electrode pads on the first surface;
a stress buffer layer formed on the first electrode pads and the first surface of the first structural body, and having a plurality of holes which expose each of the first electrode pads; and
a plurality of bumps formed to be electrically connected with the first electrode pads through the plurality of holes,
wherein the plurality of bumps include first bumps which are filled in corresponding holes of the plurality of holes and second bumps which are formed on the first bumps and the stress buffer layer and are disposed over the first electrode pads and portions of the first surface outside the first electrode pads.

2. The semiconductor device according to claim 1, further comprising:
UBMs formed between the plurality of bumps and the stress buffer layer and the first electrode pads.

3. The semiconductor device according to claim 1, wherein the plurality of holes are formed in such a way as to expose peripheral portions of the first electrode pads.

4. The semiconductor device according to claim 1, wherein the second bumps have pillar shapes.

5. The semiconductor device according to claim 1, further comprising:
a second structural body having a third surface which faces the first surface of the first structural body and a fourth surface which faces away from the third surface, wherein second electrode pads are formed on the third surface, and wherein each of the second electrode pads is simultaneously connected with at least two of the plurality of bumps.

6. The semiconductor device according to claim 5, wherein each of the first structural body and the second structural body comprises any one of a semiconductor device and a printed circuit board.

7. The semiconductor device according to claim 6, wherein the semiconductor device is any one selected from the group consisting of an image sensor, a memory semiconductor, a system semiconductor, a passive device, an active device and a sensor semiconductor.

8. The semiconductor device according to claim 6, wherein the printed circuit board is any one selected from the group consisting of a module substrate, a package substrate, a flexible substrate and a main board.

9. The semiconductor device according to claim 1, further comprising:
a second structural body having a third surface which faces the first surface of the first structural body and a fourth surface which faces away from the third surface, wherein a plurality of second electrode pads are formed on the third surface, and respectively connected with the plurality of bumps.

10. The semiconductor device according to claim 9, wherein each of the first structural body and the second structural body comprises any one of a semiconductor device and a printed circuit board.

11. The semiconductor device according to claim 10, wherein the semiconductor device is any one selected from the group consisting of an image sensor, a memory semiconductor, a system semiconductor, a passive device, an active device and a sensor semiconductor.

12. The semiconductor device according to claim 10, wherein the printed circuit board is any one selected from the group consisting of a module substrate, a package substrate, a flexible substrate and a main board.

13. A stacked semiconductor package comprising:
a stacked semiconductor chip module including a first semiconductor chip which has a first surface and a second surface facing away from the first surface and is formed, on the first surface, with first electrode pads and redistribution lines connected with the first electrode pads, a second semiconductor chip which is stacked over the first semiconductor chip and is formed, on a third surface thereof facing the first semiconductor chip, with second electrode pads, a stress buffer layer which is formed on the third surface of the second semiconductor chip and the second electrode pads and has a plurality of holes exposing each of the second electrode pads, and a plurality of bumps which are formed to be electrically connected with the second electrode pads through the plurality of holes;
a substrate supporting the stacked semiconductor chip to module; and
connection members electrically connecting the redistribution lines of the second semiconductor chip and the substrate,
wherein the plurality of bumps include first bumps which are filled in corresponding holes of the plurality of holes and second bumps which are formed on the first bumps and the stress buffer layer and are disposed over the second electrode pads and portions of the third surface outside the second electrode pads.

14. The stacked semiconductor package according to claim 13, further comprising:
UBMs formed between the plurality of bumps and the stress buffer layer and the second electrode pads.

15. The stacked semiconductor package according to claim 13, wherein the plurality of holes are formed in such a way as to expose peripheral portions of the second electrode pads of the second semiconductor chip.

16. The stacked semiconductor package according to claim 13, wherein the second bumps have pillar shapes.

17. The stacked semiconductor package according to claim 13, further comprising:
a mold member sealing an upper surface of the substrate including the stacked semiconductor chip module; and
external connection terminals mounted to a lower surface of the substrate which faces away from the upper surface.

18. The stacked semiconductor package according to claim 13, wherein each of the first semiconductor chip and the second semiconductor chip comprises any one selected from the group consisting of an image sensor, a memory semiconductor, a system semiconductor, a passive device, an active device and a sensor semiconductor.

19. The stacked semiconductor package according to claim 13, wherein the substrate is any one selected from the group consisting of a module substrate, a package substrate, a flexible substrate and a main board.
